(19) United States
(12) Patent Application Publication
(10) Pub. No.: US 2006/0118950 A1
(43) Pub. Date: Jun. 8, 2006

(54) Multi function module

(75) Inventors: Hossein Amidi, Irvine, CA (US); Kelvin A. Marino, Laguna Hills, CA (US); Satyadey Kolli, Milpitas, CA (US)

Correspondence Address: Robert E. Krebs;Thelen Reid & Priest LLP, P.O. Box 640640, San Jose, CA, 95164, US

(73) Assignee: Smart Modular Technologies, Inc., a California Corporation

(21) Appl. No.: 10/613,398

(22) Filed: Jul. 3, 2003

(51) Int. Cl. H01L 23/34

(52) U.S. Cl. 257/723

(57) ABSTRACT

A memory module has a printed circuit board with connector pins. Several memory devices are mounted on the printed circuit board. An electrical circuit connects the memory devices to the connector pins such that the connector pins have multiple functionality based on the architecture of the memory devices used.

### FIELD OF THE INVENTION

The present invention relates to a computer memory. More particularly, the present invention relates to a multi function memory module.

### BACKGROUND OF THE INVENTION

Computers use memory devices for the storage and retrieval of information. These memory devices are often mounted on a memory module to expand the memory capacity of a computer. Sockets on a main board accommodate those memory modules also known as Single Inline Memory Modules (SIMMs) or Dual Inline Memory Modules (DIMMs). With the ever-increasing need for faster computer systems, memory devices have undergone through many architectural arrangements. For illustration purposes, the following are examples of different types of memory technology: Double Data Rate Synchronous Dynamic Random Access Memory (DDR SDRAM), Fast Cycle Random Access Memory (FCRAM), and Reduced Latency Dynamic Random Access Memory (RLDRAM).

Unfortunately, system architectures also vary with the type of memory devices used. The arrangement of the circuitry on the memory module needs to match the architecture on the main board of the system. In particular, the controller and memory socket of a computing system must be compatible with the type of memory used in the system. FIGS. 1, 2, and 3 illustrate the above problem.

FIG. 1 is a diagram schematically illustrating a DDR SDRAM system overview in accordance with a prior art. The DDR SDRAM system 100 includes a processor 102, a DDR SDRAM memory controller 104, and a DDR SDRAM memory socket 106. The processor 102 communicates with the memory controller 104 with an address bus 108, a control signal bus 110, and a data bus 112. The DDR SDRAM memory controller 104 communicates with the DDR SDRAM memory socket 106 with a controller address bus 114, a controller control signal bus 116, and a controller data bus 118. The memory socket 106 receives and couples to a DDR SDRAM memory module (not shown).

FIG. 2 is a diagram schematically illustrating a FCRAM system overview in accordance with a prior art. The FCRAM system 200 includes a processor 202, a FCRAM memory controller 204, and a FCRAM memory socket 206. The processor 202 communicates with the memory controller 204 with an address bus 208, a control signal bus 210, and a data bus 212. The FCRAM memory controller 204 communicates with the FCRAM memory socket 206 with a controller address bus 214, a controller control signal bus 216, and a controller data bus 218. The memory socket 206 receives and couples to an FCRAM memory module (not shown).

FIG. 3 is a diagram schematically illustrating a RLDRAM system overview in accordance with a prior art. The RLDRAM system 300 includes a processor 302, a RLDRAM memory controller 304, and a RLDRAM memory socket 306. The processor 302 communicates with the memory controller 304 with an address bus 308, a control signal bus 310, and a data bus 312. The RLDRAM memory controller 304 communicates with the RLDRAM memory socket 306 with a controller address bus 314, a controller control signal bus 316, and a controller data bus 318. The memory socket 306 receives and couples to a RLDRAM memory module (not shown).

Thus, for example, in order to support the above three different memory technologies, a system would require three different memory modules in addition to the different memory sockets and connections supporting the different memory modules.

A need therefore exists for a single memory module to support all types of memory technologies without requiring different sockets and connections wiring for each different technology. A primary purpose of the present invention is to solve these needs and provide further, related advantages.

### BRIEF DESCRIPTION OF THE INVENTION

A memory module has a printed circuit board with connector pins. Several memory devices are mounted on the printed circuit board. An electrical circuit connects the memory devices to the connector pins such that the connector pins have multiple functionality based on the architecture of the memory devices used.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is a diagram schematically illustrating a DDR SDRAM system overview in accordance with a prior art.

FIG. 2 is a diagram schematically illustrating an FCRAM system overview in accordance with a prior art.

FIG. 3 is a diagram schematically illustrating an RLDRAM system overview in accordance with a prior art.

FIG. 4 is a diagram schematically illustrating a memory module in accordance with one embodiment of the present invention.

FIG. 5 is a diagram schematically illustrating a memory module system overview in accordance with one embodiment of the present invention.

FIG. 6 is a diagram schematically illustrating a controller for communicating with a multi-function memory module in accordance with one embodiment of the present invention.

FIG. 7 is a table schematically illustrating the pin configurations of a multi-function memory module in accordance with one embodiment of the present invention.

FIG. 8 is a flow diagram illustrating a method for mounting memory devices on a single memory module having several connector pins in accordance with one embodiment of the present invention.

FIG. 9 is a diagram schematically illustrating a memory module system overview in accordance with another embodiment of the present invention.

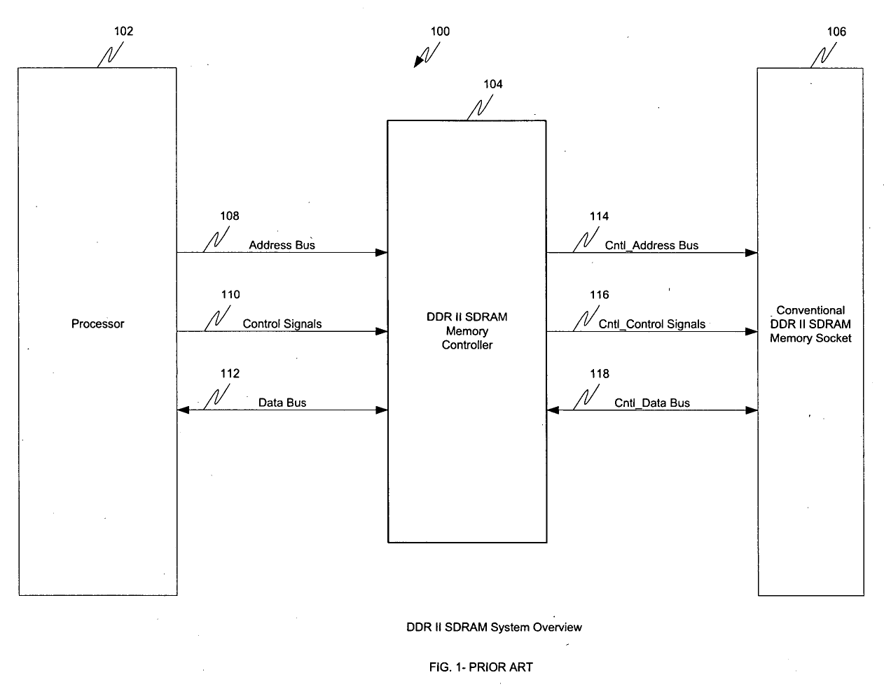

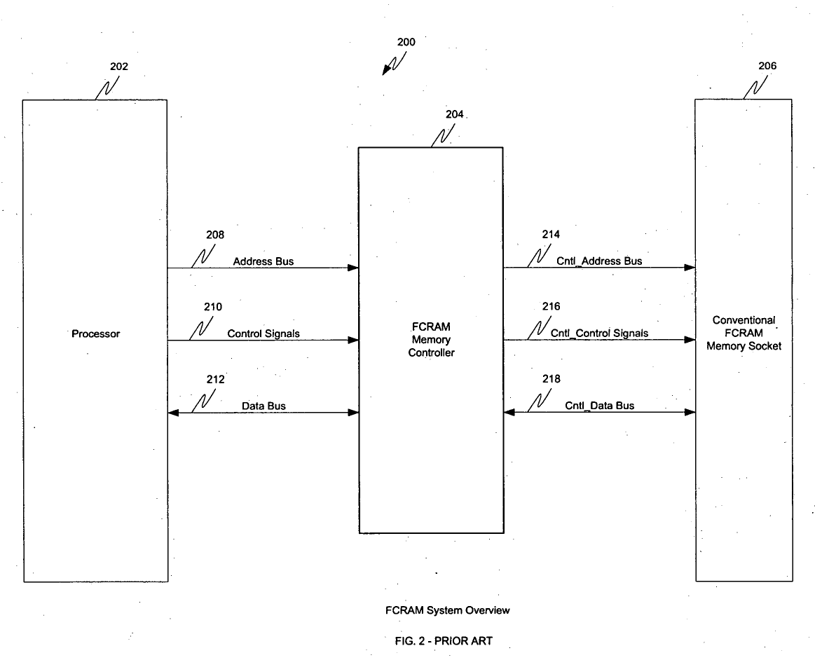

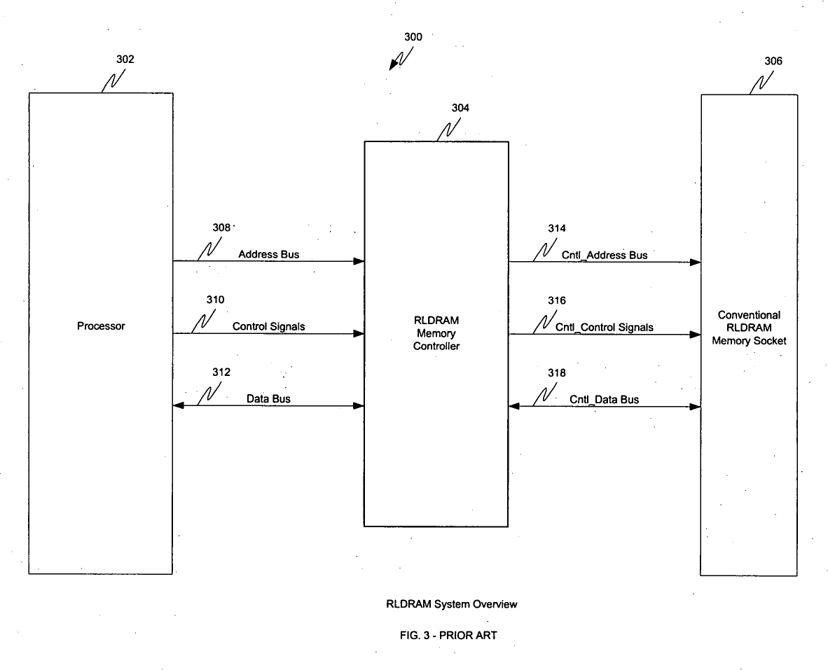

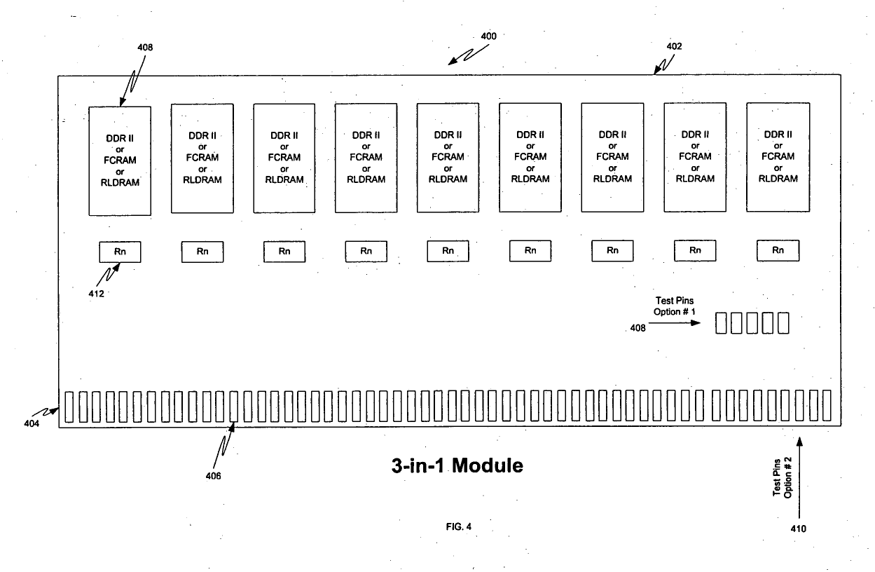

### DETAILED DESCRIPTION

Embodiments of the present invention are described herein in the context of a multi-function memory module. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

In accordance with one embodiment of the present invention, the components, process steps, and/or data structures may be implemented using various types of operating systems (OS), computing platforms, firmware, computer programs, computer languages, and/or general-purpose machines. The method can be run as a programmed process running on processing circuitry. The processing circuitry can take the form of numerous combinations of processors and operating systems, or a stand-alone device. The process can be implemented as instructions executed by such hardware, hardware alone, or any combination thereof. The software may be stored on a program storage device readable by a machine.

In addition, those of ordinary skill in the art will recognize that devices of a less general purpose nature, such as hardwired devices, field programmable logic devices (FPLDs), including field programmable gate arrays (FPGAs) and complex programmable logic devices (CPLDs), application specific integrated circuits (ASICs), or the like, may also be used without departing from the scope and spirit of the inventive concepts disclosed herein.

In accordance with one embodiment of the present invention, the method may be implemented on a data processing computer such as a personal computer, workstation computer, mainframe computer, or high performance server running an OS such as Solaris® available from Sun Microsystems, Inc. of Palo Alto, Calif., Microsoft® Windows® XP and Windows® 2000, available form Microsoft Corporation of Redmond, Wash., or various versions of the Unix operating system such as Linux available from a number of vendors. The method may also be implemented on a multiple-processor system, or in a computing environment including various peripherals such as input devices, output devices, displays, pointing devices, memories, storage devices, media interfaces for transferring data to and from the processor(s), and the like. In addition, such a computer system or computing environment may be networked locally, or over the Internet.

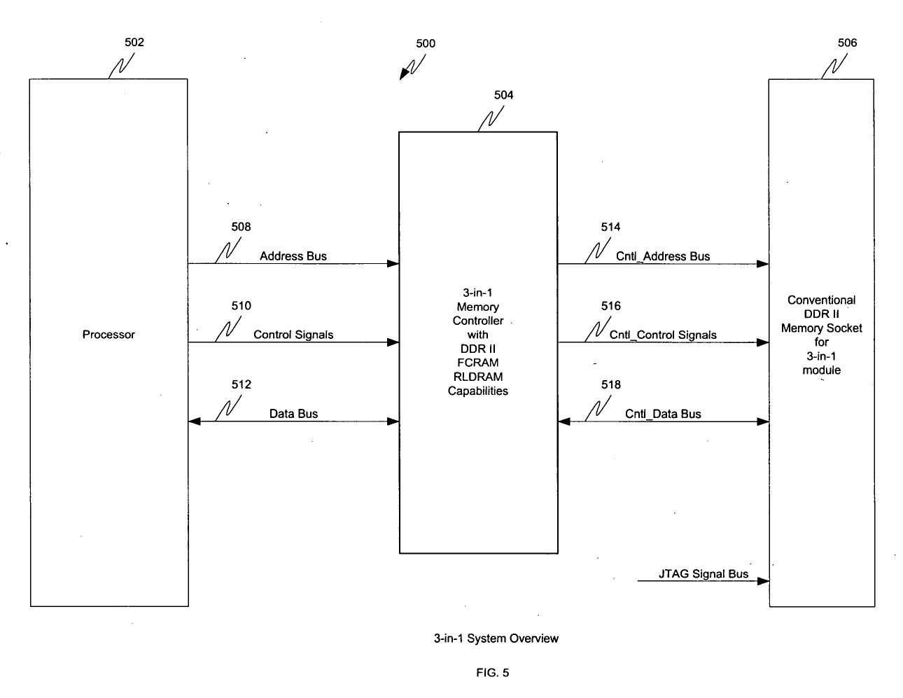

FIG. 4 illustrates a memory module 400 in accordance with one embodiment of the present invention. The memory module 400 comprises a printed circuit board (PCB) 402 having a front and rear face. Only the front face is shown in FIG. 4. The PCB 402 has a bottom side 404. Electrical connector pins 406 are located on the bottom side 404. The PCB 402 also includes several footprints 408 on which memory devices (not shown) are mounted. Each footprint 408 may accommodate a memory device. For illustration purposes, FIG. 4 illustrates a memory module 400 supporting three different types of memory technology (DDR SDRAM, FCRAM, and RLDRAM). Each memory device may have different memory architecture based on its memory technology. Each memory device may also be coupled to its corresponding resistor network 412.

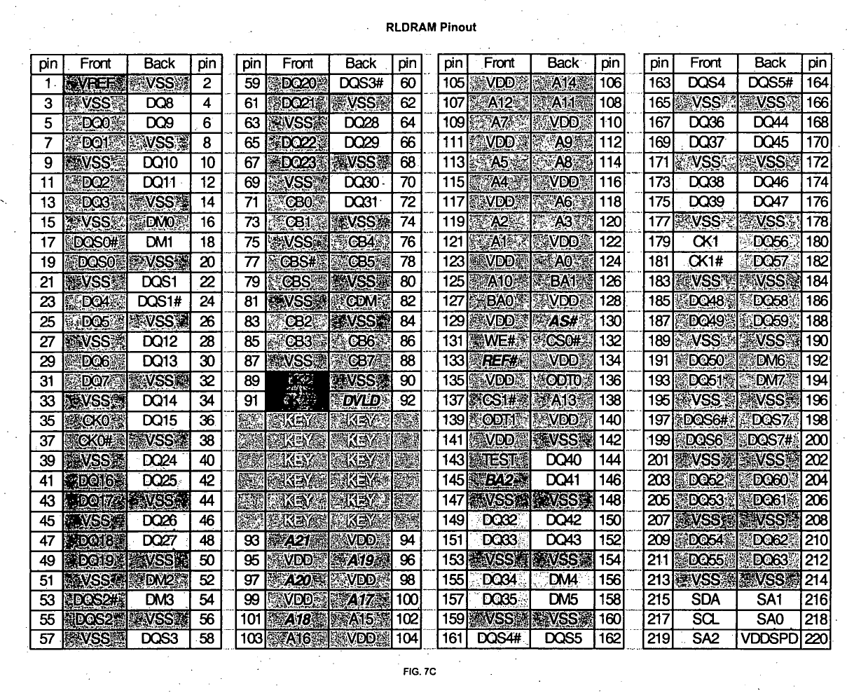

An electrical circuit (not shown) couples the memory devices to the connector pins 406 such that the connector pins 406 have multiple functionality based on the architecture of each memory device. Therefore, each connector pin 406 on the memory module 400 has multiple functionality, except for the power and ground pins. That is, each connector pin 406 may carry different signals based on the type of memory technology of the memory module attached to the footprints 408. An example of a configuration of the connector pins for supporting different types of memory technology (for example, DDR SDRAM, FCRAM, and RLDRAM) is described in more detail in FIG. 7.

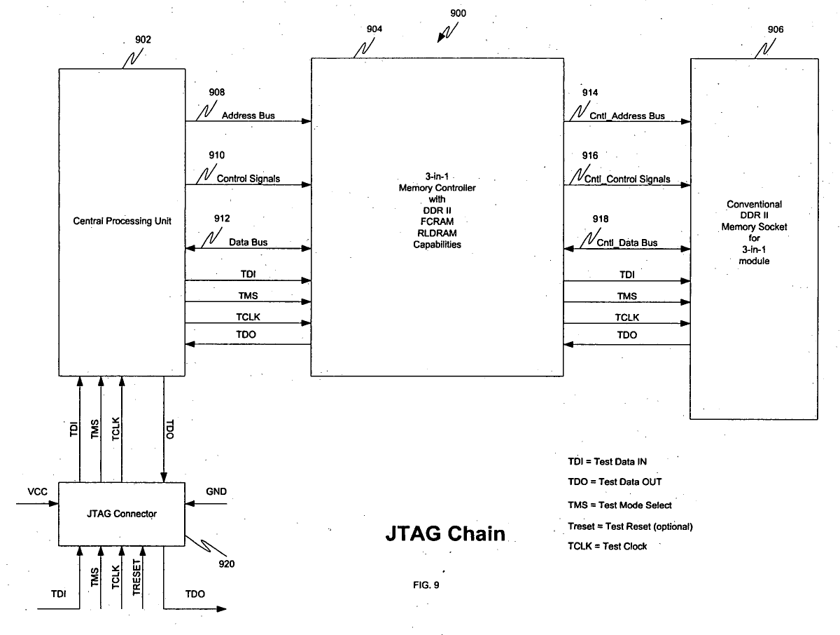

In accordance with another embodiment, testing pins may provide additional testing capability so that the connection module may be tested while plugged in to the main board. The testing pins may be located on the PCB 402 away from the bottom side 404 at 408. In accordance with another embodiment, the testing pins 402 may be also located along with the connector pins 406 on the bottom side 404 at 410. The testing pins may be, for example, JTAG pins. A JTAG pin out configuration in accordance with one embodiment of the present invention is discussed in more details in FIG. 9.

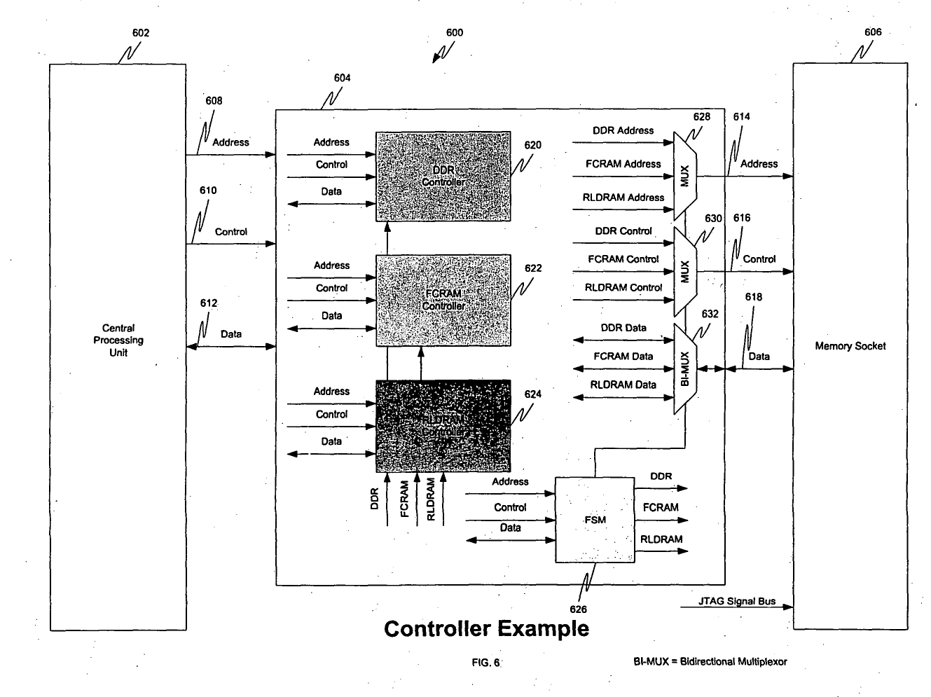

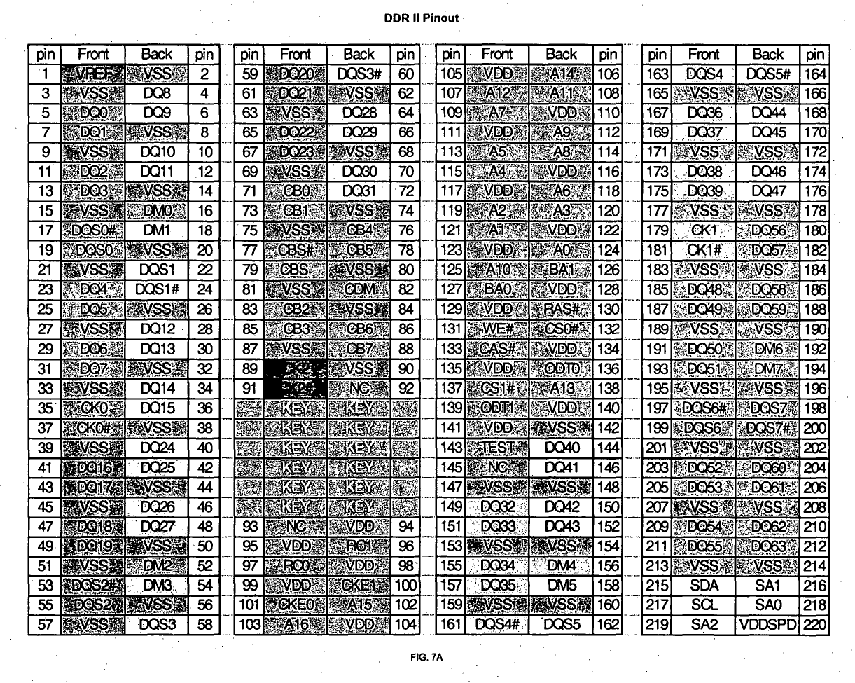

FIG. 5 is a diagram schematically illustrating a memory module system overview in accordance with one embodiment of the present invention. The system 500 includes a processor 502, a multi-capability memory controller 504, and a multi-capability memory socket 506. The processor 502 communicates with the memory controller 504 with an address bus 508, a control signal bus 510, and a data bus 512. The multi-capability memory controller 504 communicates with the multi-capability memory socket 506 with a controller address bus 514, a controller control signal bus 516, and a controller data bus 518. The memory socket 506 receives and couples to a multi-capability memory module 400 as previously illustrated in FIG. 4.

For illustration purposes, the multi-function memory socket 506 may support several types of technology such as DDR SDRAM, FCRAM, and RLDRAM. Therefore, a memory module having either DDR SDRAM, FCRAM, or RLDRAM memory devices may then be coupled with the multi-function memory socket 506.

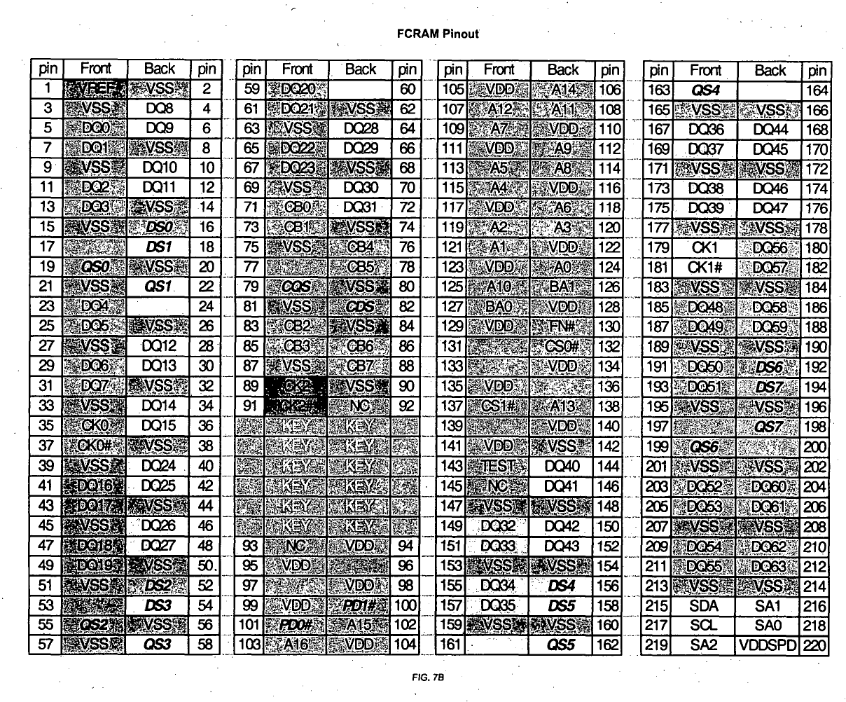

The multi-capability memory controller 504 communicates with the multi-function memory module 400 via multi-function memory socket 506. An example of a multi-capability memory controller 504 is illustrated in more detail in FIG. 6.

Therefore, a system with a multi-function memory controller 504 capable of communicating with all of the above mentioned memory architectures may only need to communicate with one memory socket 506 on the main board to drive any of these configurations, one at a time. Thus the system 500 may be capable of communicating with a multi-function memory module that may support for example, DDR SDRAM, FCRAM, or RLDRAM memory devices. Without this approach, the system would need to have three different sockets on the board to support the different memory technologies. Those of ordinary skill in the art will appreciate that the configuration of the multi-function memory module is not intended to be limiting to the above mentioned memory technology and that other memory technology can be used without departing from the inventive concepts herein disclosed. For example, other memory technology derived from the above examples may be used such as FCRAM III or RLDRAM II.

In accordance with another embodiment, a JTAG pin out in the above multi-function memory module may provide additional testing capability so that the connection module may be tested while plugged in to the main board. The JTAG pin out configuration is discussed in more details in FIG. 9.

FIG. 6 is a diagram schematically illustrating a multi-function controller 604 for communicating with a multi-function memory module in accordance with one embodiment of the present invention. The system 600 includes a processor 602, a multi-capability memory controller 604, and a multi-capability memory socket 606. The processor 602 communicates with the memory controller 604 with an address bus 608, a control signal bus 610, and a data bus 612. The multi-capability memory controller 604 communicates with the multi-capability memory socket 606 with a controller address bus 614, a controller control signal bus 616, and a controller data bus 618. The memory socket 606 receives a multi-capability memory module 400 as previously illustrated in FIG. 4.

In accordance with one embodiment of the present invention, the multi-function controller 604 may be able to communicate with several types of memory devices such as DDR SDRAM, FCRAM, or RLDRAM. The multi-function controller 604 may include a DDR controller 620, a FCRAM controller 622, and a RLDRAM controller 624. Each controller 620, 622, and 624 may communicate with the processor 602 via the address bus 608, control bus 610, and data bus 612. A Finite State Machine (FSM) 626 interfaces between the signals from the address bus 608, control bus 610, data bus 612 and the signals with the memory socket 606 through multiplexors 628, 630, and 632. A first multiplexor 628 channels address signals to the address bus 614 depending on the type of memory device technology (for example, DDR address, FCRAM address, or RLDRAM address). A second multiplexor 630 channels signals to the control bus 616 depending on the type of memory device technology (for example, DDR control, FCRAM control, RLDRAM control). A third multiplexor 632 channels signals to the data bus 618 depending on the type of memory device technology (for example, DDR data, FCRAM data, RLDRAM data). Those of ordinary skill in the art will appreciate that the configuration of the multi-function memory controller shown above is not intended to be limiting and that other configurations can be used without departing from the inventive concepts herein disclosed.

FIGS. 7A, 7B, and 7C are tables schematically illustrating the pin configurations of a multi-function memory module in accordance with one embodiment of the present invention. In particular, FIG. 7A illustrates a 220-pin configuration for a DDR SDRAM. FIG. 7B illustrates a 220-pin configuration for a FCRAM. FIG. 7C illustrates a 220-pin configuration for an RLDRAM.

The following is a table of abbreviations used in FIGS. 7A, 7B, and 7C:

VREF=Reference Voltage

VSS=Ground

VDD=Voltage

DQx=Data line x

DQSx#=Data Strobe line x

CKx=Clock positive

CKx#=Clock negative

DMx=Data Mask

CBx=ECC Data line x

ECC=Error Correction Circuitry

CBS=CB Strobe line positive

CBS#=CB Strobe line negative

KEY=Module key location for socket insertion

NC=No Connect

RCx=Register Configuration Pin

CKEx=Clock Enable

Ax=Address

BAx=Internal Bank Address

CDM=Check-bit Data Mask

RAS#=Row Address Strobe

CAS#=Column Address Strobe

WE#=Write Enable

CSx#=Chip Select Signal

ODTx=On-Die termination

SDA=Serial Data Signal for EEPROM

SAx=Serial Address line

SCL=Serial Clock

VDDSPD=SPD Clock

SPD=Serial Presence Detect

QSx=Data Mask Strobe

DSx=Data Strobe

CQS=Check-bit Mask Strobe

PDx#=Power Down Control

CDS=Check-bit Data Strobe

FN#=Function Control

DVLD=Data Valid

REF#=Auto Refresh

AS#=Address Strobe

As an example, pin 101 on the memory module carries the CKE0 signal when it is configured for DDR SDRAM. The same pin 101 may also carry signal A18 when it is configured as RLDRAM, and signal PD0# when is it configured as FCRAM. The table in FIG. 7 illustrates the location for any particular signal based on the type of memory technology used.

In accordance with one embodiment of the present invention, the above illustrated pin configuration may be derived from a standard DDR II connector pin configuration. One advantage of having the pin configuration derived from a standard DDR II pin configuration is that the memory module with the above pin configuration would be compatible with a standard DDR II pinout.

In accordance with another embodiment of the present invention, the memory module may incorporate other memory technologies such as FCRAM or RLDRAM. For example, a memory module incorporating FCRAM technology would require a controller compatible with FCRAM settings.

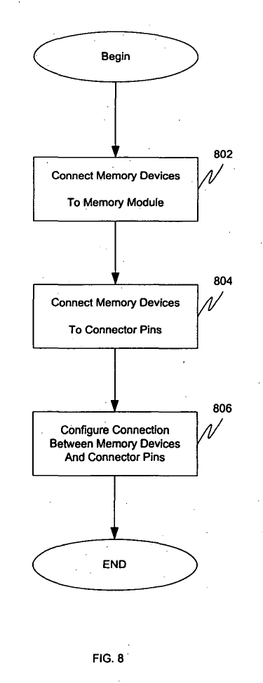

FIG. 8 is a flow diagram illustrating a method for mounting memory devices with different configurations on a single memory module having several connector pins in accordance with one embodiment of the present invention. At 802 the memory devices are coupled on the memory module. The architecture of the memory devices may belong to one type of memory technology such as, for example, DDR SDRAM, RLD RAM, or FCRAM. At 804, the memory devices are coupled to the connector pins. At 806, the connection between the memory devices and the connector pins is configured such that the connector pins have multiple functionalities based on the architecture of the memory devices.

FIG. 9 is a diagram schematically illustrating a memory module system overview in accordance with another embodiment of the present invention. The system 900 includes a processor 902, a multi-capability memory controller 904, and a multi-capability memory socket 906. The processor 902 communicates with the memory controller 904 with an address bus 908, a control signal bus 910, and a data bus 912. The multi-capability memory controller 904 communicates with the multi-capability memory socket 906 with a controller address bus 914, a controller control signal bus 916, and a controller data bus 918. The memory socket 906 receives and couples to a multi-capability memory module 400 as previously illustrated in FIG. 4.

For illustration purposes, the multi-function memory socket 906 may support several types of technology such as DDR SDRAM, FCRAM, and RLDRAM. Therefore, a memory module having either DDR SDRAM, FCRAM, or RLDRAM memory devices may then be coupled with the multi-function memory socket 906.

The multi-capability memory controller 904 communicates with the multi-function memory module 400 via multi-function memory socket 906. An example of a multi-capability memory controller 904 is illustrated in more detail in FIG. 6.

Therefore, a system with a multi-function memory controller 904 capable of communicating with all of the above mentioned memory architectures may only need to communicate with one memory socket 906 on the main board to drive any of these configurations, one at a time. Thus the system 900 may be capable of communicating with a multi-function memory module that may support for example, DDR SDRAM, FCRAM, or RLDRAM memory devices. Without this approach, the system would need to have three different sockets on the board to support the different memory technologies. Those of ordinary skill in the art will appreciate that the configuration of the multi-function memory module is not intended to be limiting to the above mentioned memory technology and that other memory technology can be used without departing from the inventive concepts herein disclosed.

FIG. 9 further illustrates a JTAG connector 920 communicating with the above multi-function memory module to provide additional testing capability so that the memory module may be tested while plugged in to the main board. The JTAG connector 920 communicates with the memory socket 906 through the processor 902, the memory controller 904, and the socket 906.

The following is a table of abbreviations in FIG. 9:

TDI=Test Data IN

TDO=Test Data OUT

TMS=Test Mode Select

Treset=Test Reset (optional)

TCLK=Test Clock

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims.

What is claimed is:

1. A memory module comprising:
a printed circuit board having a plurality of connector pins;
a plurality of memory devices mounted on said printed circuit board; and
an electrical circuit coupling said plurality of memory devices to said plurality of connector pins such that said plurality of connector pins has multiple functionality based on the architecture of said plurality of memory devices.

2. The memory module according to claim 1 wherein said memory device is selecting from the group consisting of Double Data Rate Synchronous Dynamic Random Access Memory (DDR SDRAM), a Fast Cycle Random Access Memory (FCRAM), and a Reduced Latency Dynamic Random Access Memory (RLDRAM).

3. The memory module according to claim 1 wherein said plurality of connector pins engages with a memory socket, said memory socket communicating with a memory controller.

4. The memory module according to claim 3 wherein said memory controller includes:
a plurality controllers, each controller corresponding to an architecture of the memory devices;
an Finite State Machine (FSM) coupled to said plurality of controllers;
an address multiplexor coupled to said FSM, said address multiplexor communicating with said memory socket;
a control multiplexor coupled to said FSM, said control multiplexor communicating with said memory socket; and
a data multiplexor coupled to said FSM, said data multiplexor communicating with said memory socket.

5. The memory module according to claim 1 further comprising:
a second electrical circuit for testing said plurality of memory devices, said second electrical circuit coupled to said plurality of memory devices; and
a plurality of testing pins coupled to said second electrical circuit.

6. The memory module according to claim 5 wherein said second electrical circuit supports a JTAG configuration.

7. The memory module according to claim 1 wherein said plurality of connector pins includes 220 pins.

8. A computer comprising:
a main board; and
a memory module coupled to said main board, said memory module including:
a printed circuit board having a plurality of connector pins; and
a plurality of memory devices mounted on said printed circuit board,
an electrical circuitry electrically coupling said plurality of memory devices to said plurality of connector pins such that said plurality of connector pins has multiple functionality based on an architecture of each memory device.

9. The computer of claim 8 wherein the architecture of the memory devices is selected from the group consisting of a DDR SDRAM, a FCRAM, and a RLDRAM.

10. A method for mounting a plurality of memory devices with different configurations on a single memory module having a plurality connector pins, said method comprising:
electrically coupling the memory devices on the memory module, each memory device having different configurations;
connecting the memory devices to the plurality of connector pins; and
configuring the connection between the memory devices and the plurality of connector pins such that the connector pins have multiple functionalities based on the architecture of the memory devices.

11. The method of claim 10 wherein the architecture of the memory devices is selected from the group consisting of a DDR SDRAM, a FCRAM, and a RLDRAM.
